(19) United States
(12) Patent Application Publication
(10) Pub. No.: US 2013/0027873 A1
(43) Pub. Date: Jan. 31, 2013

(54) ELECTRONIC DEVICE

(71) Applicants: Ying-Shan Chen, Taipei City (TW); Ching-Ya Tu, Taipei City (TW); Chang-Yuan Wu, Taipei City (TW); Hui-Lian Chang, Taipei City (TW)

(72) Inventors: Ying-Shan Chen, Taipei City (TW); Ching-Ya Tu, Taipei City (TW); Chang-Yuan Wu, Taipei City (TW); Hui-Lian Chang, Taipei City (TW)

(73) Assignee: COMPAL ELECTRONICS, INC., Taipei City (TW)

(21) Appl. No.: 13/558,359

(22) Filed: Jul. 26, 2012

Related U.S. Application Data
(60) Provisional application No. 61/511,978, filed on Jul. 26, 2011.

(51) Int. Cl. H05K 7/20; G06F 1/20

(52) U.S. Cl. 361/679.46; 361/690; 361/695; 361/692

(57) ABSTRACT

An electronic device includes a main body and a rotating base. The rotating base has a first vent and is pivoted at the main body and adapted to rotate between an operating position and a retracted position relatively to the main body. When the rotating base is located at the operating position, the first vent is exposed out of the main body, and when the rotating base is located at the retracted position, the first vent is retracted into the main body.

### CROSS-REFERENCE TO RELATED APPLICATION

This application claims the priority benefit of U.S. provisional application serial. No. 61/511,978, filed Jul. 26, 2011. The entirety of the above-mentioned patent application is hereby incorporated by reference herein and made a part of this specification.

### BACKGROUND OF THE INVENTION

1. Field of the Invention

The present invention generally relates to an electronic device, and more particularly, to an electronic device able to retract the vents thereof.

2. Description of Related Art

In recent years, along with the increasingly developed technology industries, electronic devices, such as notebook computers (NB), personal digital assistant (PDA) and smart phones, have frequently appeared in our daily lives. The type and the usage functions of the electronic devices become more diversity; in particular, the convenience and the practicality of these electronic devices make the electronic devices more popular to suit different purposes.

However, the electronic device today is persuading thin and light design, so that in a limited case space thereof, it is difficult to employ cooling components or to increase the space for heat dissipation. Therefore, how to make electronic devices with good heat dissipation effect indeed is a big problem for today's electronic device design.

### SUMMARY OF THE INVENTION

Accordingly, the present invention is directed to an electronic device, wherein the vents thereof can be retracted inside the electronic device.

The invention provides an electronic device, which includes a main body and a rotating base. The rotating base has a first vent and is pivoted at the main body and adapted to rotate between an operating position and a retracted position relatively to the main body. When the rotating base is located at the operating position, the first vent is exposed out of the main body, and when the rotating base is located at the retracted position, the first vent is retracted into the main body.

In an embodiment of the present invention, the above-mentioned electronic device further includes a fan module, which includes a wind-guiding cover assembly, and the wind-guiding cover assembly is connected between the main body and the rotating base and has a telescopic segment.

In an embodiment of the present invention, the above-mentioned fan module further includes a fan and the fan is fixed at the main body or the rotating base.

In an embodiment of the present invention, the above-mentioned electronic device further includes a motherboard disposed at the main body or the rotating base.

In an embodiment of the present invention, the above-mentioned main body has a second vent, and when the rotating base is located at the retracted position, the first vent is located at a side of the second vent.

In an embodiment of the present invention, the above-mentioned telescopic segment includes a flexible portion, when the rotating base is located at the retracted position, the flexible portion is bent to shorten the telescopic segment, and when the rotating base is located at the operating position, the flexible portion is unfolded to lengthen the telescopic segment.

In an embodiment of the present invention, the above-mentioned telescopic segment includes a plurality of folding elements, when the rotating base is located at the retracted position, each of the folding elements is bent to shorten the telescopic segment, and when the rotating base is located at the operating position, each of the folding elements is unfolded to lengthen the telescopic segment.

In an embodiment of the present invention, the above-mentioned telescopic segment includes a plurality of shells, when the rotating base is located at the retracted position, the shells are sleeved by each other to shorten the telescopic segment, and when the rotating base is located at the operating position, the shells sequentially lean against each other to lengthen the telescopic segment.

In an embodiment of the present invention, the above-mentioned electronic device further includes a first set of cooling fins and a second set of cooling fins. The first set of cooling fins is disposed at the main body, and the second set of cooling fins is disposed at the rotating base and dislocated from the first set of cooling fins, in which when the rotating base is located at the retracted position, the second set of cooling fins is located at a side of the first set of cooling fins.

In an embodiment of the present invention, the above-mentioned electronic device claimed in claim further includes a first set of cooling fins and a second set of cooling fins The first set of cooling fins is disposed at the main body and has a plurality of first cooling fins, and the second set of cooling fins is disposed at the rotating base and aligned with the first set of cooling fins and has a plurality of second cooling fins, in which when the rotating base is located at the retracted position, the first cooling fins and the second cooling fins are alternately arranged.

Based on the description above, the invention provides an electronic device, in which the first vent is disposed on the rotating base and the rotating base can rotate between the operating position and the retracted position relatively to the main body. When the rotating base is located at the operating position, the first vent is exposed by the electronic device so that the fan is able to blow an air-flow and the air-flow flows through the first vent to exit from the electronic device. In this way, the first vent can be exposed out of the main body to assist cooling the electronic device.

Reference will now be made in detail to the present preferred embodiments of the invention, examples of which are illustrated in the accompanying drawings. Wherever possible, the same reference numbers are used in the drawings and the description to refer to the same or like parts.

### BRIEF DESCRIPTION OF THE DRAWINGS

FIG. 1 is a schematic diagram of an electronic device according to an embodiment of the present invention.

FIG. 2 is a diagram showing the rotating base of FIG. 1 rotates relatively to the main body.

FIG. 3 is a side-view diagram of the electronic device of FIG. 1.

FIG. 4 is a side-view diagram showing the rotating base of FIG. 3 rotates relatively to the main body.

FIG. 5 is a side-view diagram of an electronic device according to another embodiment of the present invention.

FIG. 6 is a schematic diagram of the wind-guiding cover assembly of FIG. 3.

FIG. 7 is a schematic diagram of the wind-guiding cover assembly of FIG. 4.

FIG. 8 is a schematic diagram of a wind-guiding cover assembly according to another embodiment of the present invention.

FIG. 9 is a schematic diagram showing the shells in FIG. 8 slide relatively to each other.

FIG. 10 is a side-view diagram of an electronic device according to yet another embodiment of the present invention.

FIG. 11 is a side-view diagram of an electronic device according to yet another embodiment of the present invention.

FIG. 12 is a partial three-dimensional diagram of the electronic device of FIG. 3.

FIG. 13 is a partial three-dimensional diagram of the electronic device of FIG. 4.

FIG. 14 is a partial three-dimensional diagram of an electronic device according to yet another embodiment of the present invention.

FIG. 15 is a diagram showing the rotating base of FIG. 14 rotates relatively to the main body.

### DESCRIPTION OF THE EMBODIMENTS

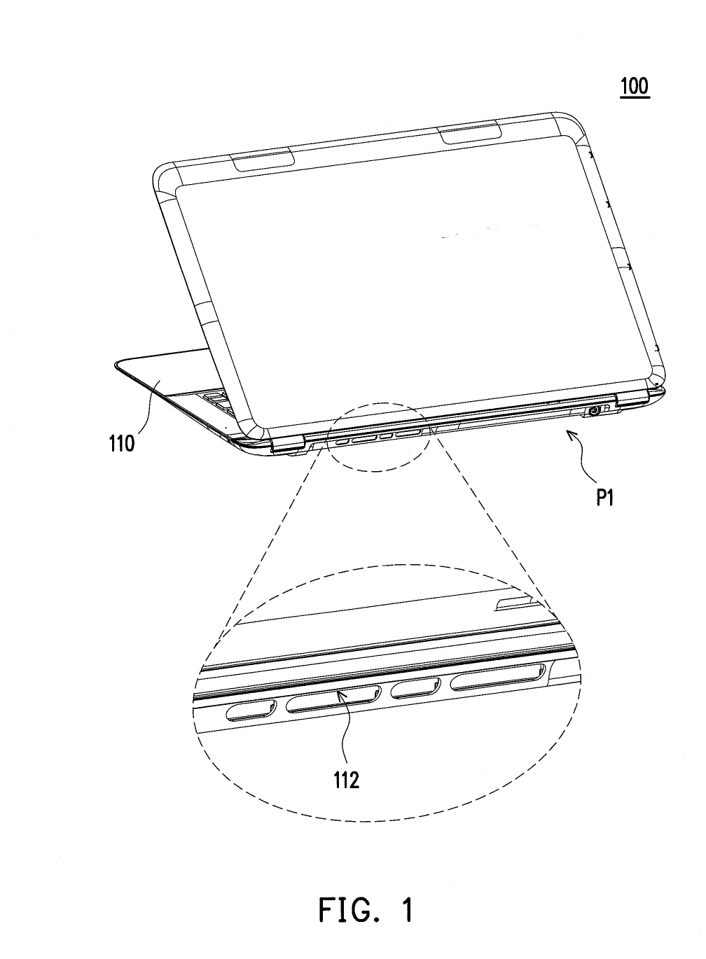

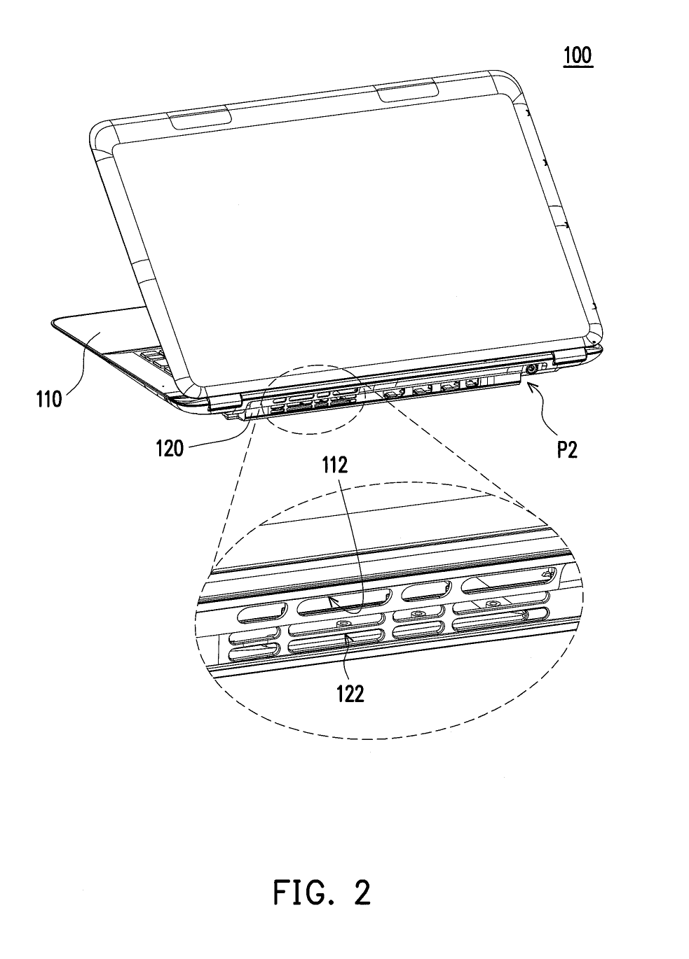

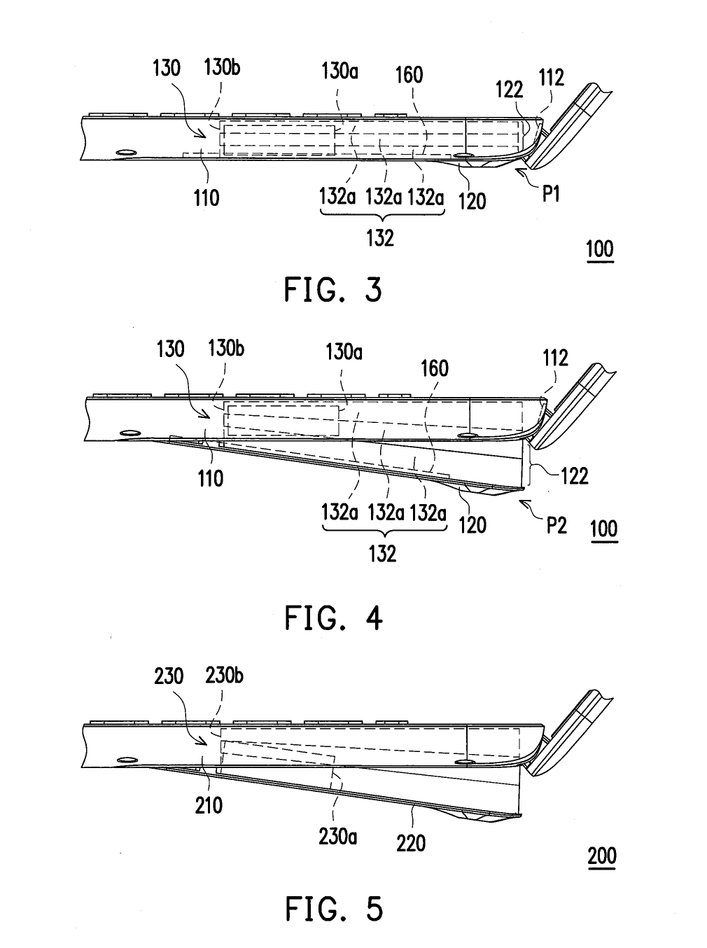

Referring to FIGS. 1-4, in the embodiment, the electronic device 100 is, for example, a notebook computer. In other embodiments, the electronic device 100 can be other electronic devices, which the present invention is not limited to. The electronic device 100 includes a main body 110, a rotating base 120 and a fan module 130. The rotating base 120 is pivoted at the main body 110 and adapted to rotate between a retracted position P1 (as shown by FIGS. 1 and 3) and an operating position P2 (as shown by FIGS. 2 and 4) relatively to the main body. Referring to FIGS. 3 and 4, in the embodiment, the motherboard 160 of the electronic device 100, for example, is disposed on the rotating base 120 and can rotates with the rotating base 120, which the present invention is not limited to. In other embodiments, the motherboard 160 of the electronic device 100 can be disposed on the main body 110, but does not rotate with the rotating base 120.

The fan module 130 includes a fan 130a and a wind-guiding cover assembly 130b. The fan 130a is fixed at the main body 110 and the wind-guiding cover assembly 130b is connected between the main body 110 and the rotating base 120. When the rotating base 120 is located at the retracted position P1 as shown by FIG. 1, the rotating base 120 is closed at the main body 110 so as to hide the fan module 130 in the main body 110; when the rotating base 120 is located at the operating position P2 as shown by FIG. 2, the rotating base 120 is unfolded at the main body 110 to make the main body 110 expose the fan module 130. The wind-guiding cover assembly 130b has a telescopic segment 132 and the telescopic segment 132 is suitable for elongation (as shown by FIG. 4) or shortening (as shown by FIG. 3) along with the rotating of the rotating base 120 relatively to the main body 110.

Under the above-mentioned layout, the rotating base 120 can rotate relatively to the main body so as to expose the fan module 130 and adjust the flowing direction of the cooling air-flow provided by the fan 130a of the fan module 130, so that the cooling air-flow is easier to flow into the electronic device 100 from the space between the main body 110 and the rotating base 120 to advance the cooling effect of the fan module 130. The wind-guiding cover assembly 130b connected between the main body 110 and the rotating base 120 is used for guiding and shield the cooling air-flow. The telescopic segment 132 of the wind-guiding cover assembly 130b is suitable for elongation or shortening along with the rotating of the rotating base 120 relatively to the main body 110 so that the rotating base 120 can smoothly rotate relatively to the main body 110, and meanwhile, the cooling air-flow is definitely guided and shielded by the wind-guiding cover assembly 130b. As a result, the fan module 130 has a good cooling effect.

In the embodiment, the rotating base 120 has a first vent 122 and the main body 110 has a second vent 112. When the rotating base 120 is located at the retracted position P1, the first vent 122 is retracted into the main body 110 as shown by FIG. 1 and the first vent 122 is located at a side of the second vent 112. Therefore, the air-flow blown by the fan 130a sequentially flows out from the rotating base 120 via the first vent 122, and then flows out from the main body 110 via the second vent 112 so that the electronic device 100 has cooling function. In this way, even though the rotating base 120 is retracted into the main body 110, there is no negative influence on the cooling effect of the main body 110. On the other hand, as shown by FIG. 2, when the rotating base 120 is located at the operating position P2, the first vent 122 is exposed out of the main body 110 along with the rotating the rotating base 120, and at the time the first vent 122 and the second vent 112 are in presence of up-down parallel disposing. As a result, the air-flow blown by the fan 130a can respectively and simultaneously flow out of the electronic device 100 via both the first vent 122 and the second vent 112. Consequently, when the rotating base 120 is located at the operating position P2, the ventilation area of the electronic device 100 is increased so as to advance the cooling effect of the electronic device 100.

In the embodiment, the fan 130a is fixed at the main body 110, which the present invention is not limited to. In following, some diagrams and embodiments are given to explain the present invention. FIG. 5 is a side-view diagram of an electronic device according to another embodiment of the present invention. In the electronic device 200 of FIG. 5, the layout of the main body 210, the rotating base 220 and the wind-guiding cover assembly 230b is the same as the layout of the main body 110, the rotating base 120 and the wind-guiding cover assembly 130b in FIGS. 3 and 4, which is omitted to describe. The difference of the electronic device 200 from the electronic device 100 rests in the fan 230a of the fan module 230 is fixed on the rotating base 220 so as to be able move along with the rotating of the rotating base 220. However, depending on the design requirement, the fan can be fixed on the main body or on the rotating base as well.

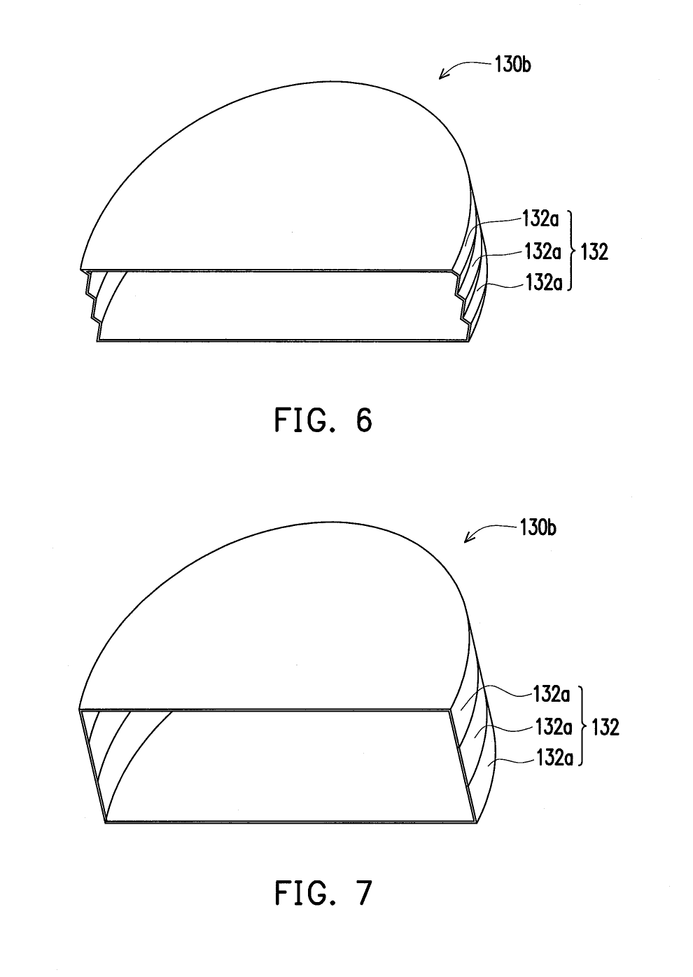

FIG. 6 is a schematic diagram of the wind-guiding cover assembly of FIG. 3 and FIG. 7 is a schematic diagram of the wind-guiding cover assembly of FIG. 4. In more details, in the embodiment of FIGS. 3 and 4, telescopic segment 132 of the wind-guiding cover assembly 130b includes a plurality of folding elements 132a (there are three herein) and the folding elements 132a are sequentially connected to each other. When the rotating base 120 is located at the retracted position P1 as shown by FIGS. 1 and 3, each of the folding elements 132a is bent to shorten the telescopic segment 132 as shown by FIG. 6. When the rotating base 120 is located at the operating position as shown by FIGS. 2 and 4, each of the folding elements 132a is unfolded to lengthen the telescopic segment 132 as shown by FIG. 7. In other embodiments, the telescopic segment 132 can include a flexible portion and the flexible portion is a flexible structure made of, for example, rubber or other appropriate elastic materials. When the rotating base 120 is located at the retracted position P1, the flexible portion is bent through the elasticity thereof to shorten the telescopic segment 132; when the rotating base 120 is located at the operating position P2, the flexible portion is sprung out through the elasticity thereof to lengthen the telescopic segment 132.

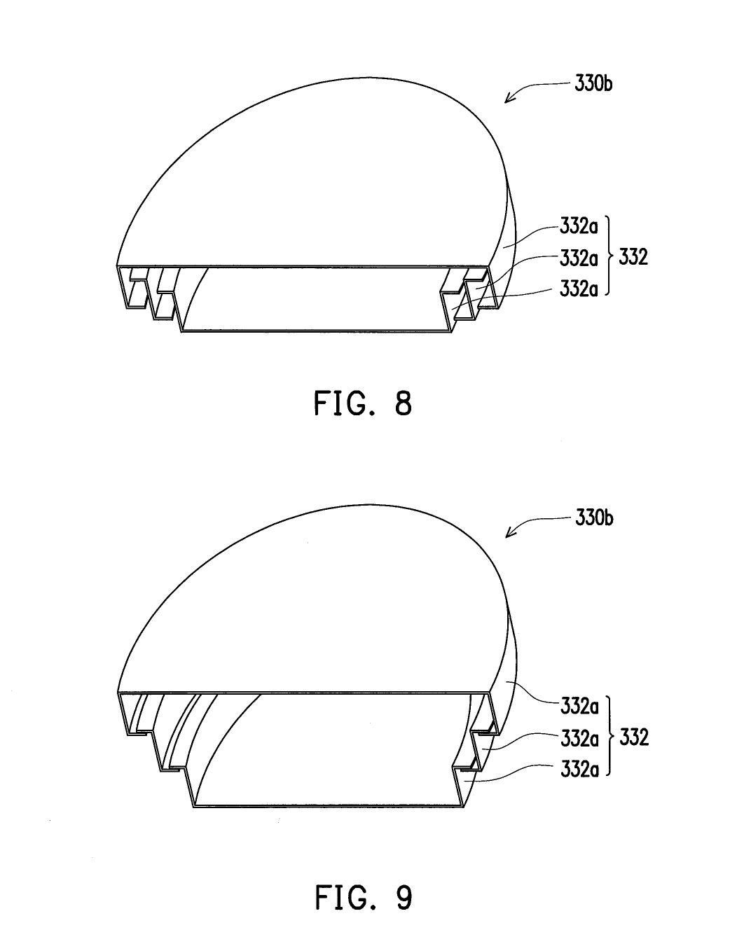

FIG. 8 is a schematic diagram of a wind-guiding cover assembly according to another embodiment of the present invention and FIG. 9 is a schematic diagram showing the shells in FIG. 8 slide relatively to each other. The wind-guiding cover assembly 130b in FIGS. 6 and 7 can be replaced by the wind-guiding cover assembly 330b in FIGS. 8 and 9, and is suitable for elongation or shortening along with the rotating of the rotating base relatively to the main body. The structure and the elongation or shortening of the wind-guiding cover assembly 330b is described in more details in following. In the embodiment of FIGS. 8 and 9, telescopic segment 332 of the wind-guiding cover assembly 330b includes a plurality of shells 332a, the shells 332a are slidably connected to each other in sequence, and each of the shells 332a is adapted to slide relatively to the adjacent shells 332a. When the rotating base is located at the retracted position, the shells 332a are sleeved by each other to shorten the telescopic segment 332 as shown by FIG. 8; when the rotating base is located at the operating position, the shells 332a slide relatively to each other until they sequentially lean against each other as shown by FIG. 9 so as to lengthen the telescopic segment 332.

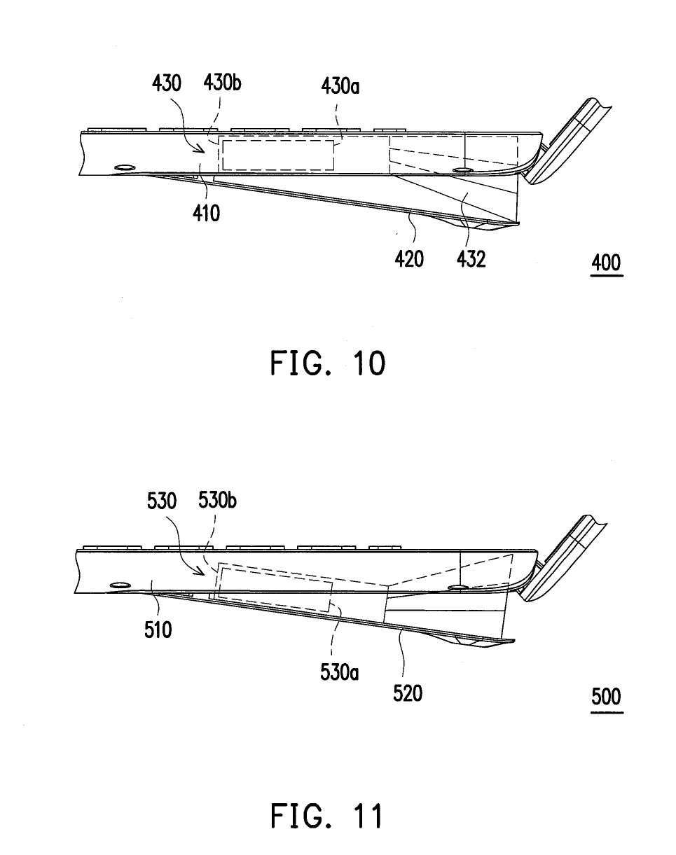

FIG. 10 is a side-view diagram of an electronic device according to yet another embodiment of the present invention. In the electronic device 400 of FIG. 10, the layout of the main body 410, the rotating base 420 and the fan 430a is the same as the layout of the main body 110, the rotating base 120 and the fan 130a in FIGS. 3 and 4, which is omitted to describe. The difference of the electronic device 400 from the electronic device 100 rests in the structure of the wind-guiding cover assembly 430b of the fan module 430. In more details, in comparison with the telescopic segment 132 as shown by FIGS. 3 and 4 which has a larger elongation range to make the wind-guiding cover assembly 130b adapted to integrally elongate or shorten, the telescopic segment 432 of FIG. 10 has a smaller elongation range to make the wind-guiding cover assembly 430b adapted to elongate or shorten only within a local area. In other embodiments, the telescopic segment can have other appropriate elongation ranges, which the present invention is not limited to.

In the embodiment of FIG. 10, the fan 430a is fixed at the main body 410, which the present invention is not limited to and more examples with the diagrams are given in following. FIG. 11 is a side-view diagram of an electronic device according to yet another embodiment of the present invention. In the electronic device 500 of FIG. 11, the layout of the main body 510, the rotating base 520 and the wind-guiding cover assembly 530b is the similar to the layout of the main body 410, the rotating base 420 and the wind-guiding cover assembly 430b in FIG. 10, which is omitted to describe. The difference of the electronic device 500 from the electronic device 400 rests in the fan 45a of the fan module 530 is fixed on the rotating base 520 and able to move along with the rotating of the rotating base 520. Depending on the design requirement, the fan can be fixed on the main body or the rotating base, which the present invention is not limited to.

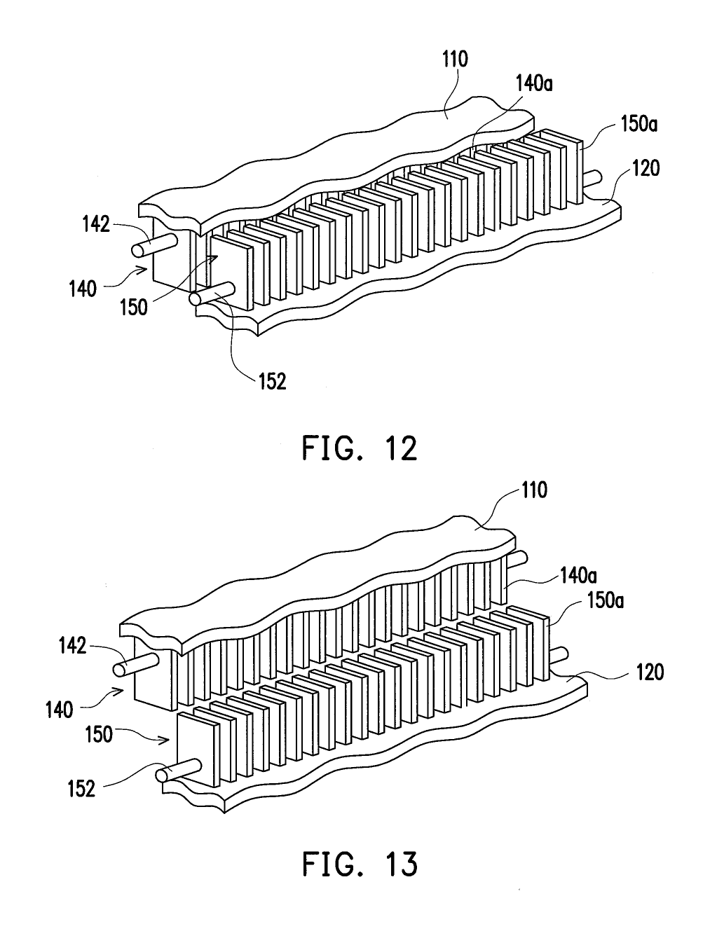

FIG. 12 is a partial three-dimensional diagram of the electronic device of FIG. 3 and FIG. 13 is a partial three-dimensional diagram of the electronic device of FIG. 4. Referring to FIGS. 12 and 13, in the embodiment, the electronic device 100 as shown by FIGS. 3 and 4 further includes a first set of cooling fins 140 and a second set of cooling fins 150. The first set of cooling fins 140 is disposed at the main body 110 and includes a plurality of cooling fins 140a and a heat pipe 142. The heat pipe 142 connects the cooling fins 140a so that the first set of cooling fins 140 receives the thermal energy of the heat-generating components inside the electronic device 100 through the heat pipe 142. The second set of cooling fins 150 is disposed at the rotating base 120 and includes a plurality of cooling fins 150a and a heat pipe 152. The heat pipe 152 connects the cooling fins 150a so that the second set of cooling fins 150 receives the thermal energy of the heat-generating components inside the electronic device 100 through the heat pipe 152. The second set of cooling fins 150 and the first set of cooling fins 140 are disposed in dislocated way therebetween. In this way, when the rotating base 120 is closed to the retracted position P1 as shown by FIG. 3 from the operating position P2 as shown by FIG. 4, the second set of cooling fins 150 would move to the position of FIG. 12 from the position of FIG. 13 to be located at a side of the first set of cooling fins 140. Therefore, the first set of cooling fins 140 on the main body 110 and the second set of cooling fins 150 on the rotating base 120 are not interfered by each other so as to make the whole structure smoothly act.

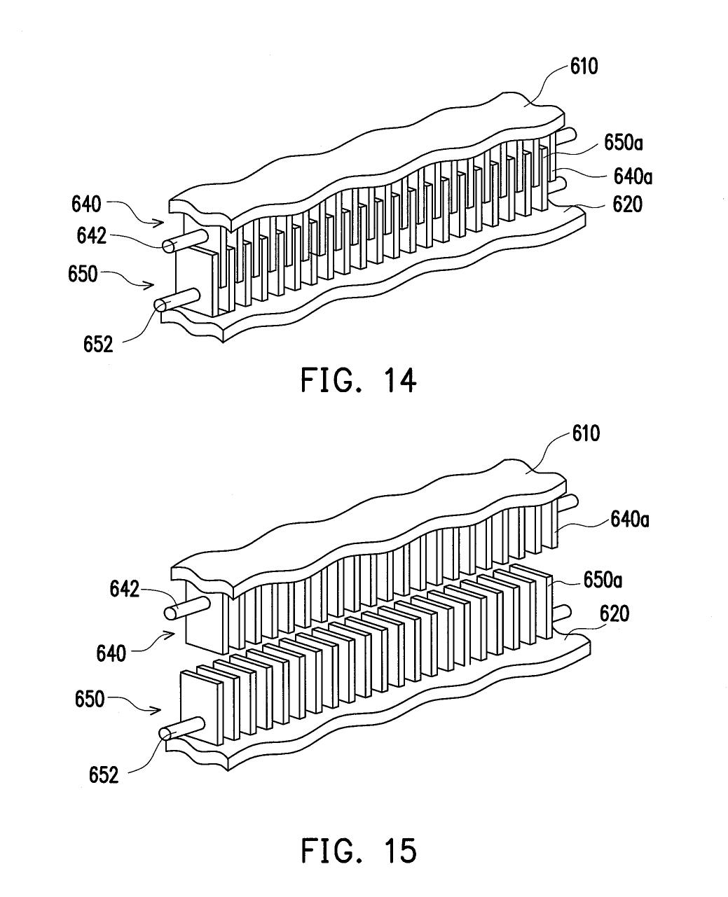

FIG. 14 is a partial three-dimensional diagram of an electronic device according to yet another embodiment of the present invention and FIG. 15 is a diagram showing the rotating base of FIG. 14 rotates relatively to the main body. The layout of the main body 610 and the rotating base 620 in FIGS. 14 and 15 is the same as the layout of the main body 110 and the rotating base 120 in FIGS. 12 and 13. The difference of the embodiment in FIGS. 14 and 15 from the embodiment in FIGS. 12 and 13 rests in the layout of the sets of cooling fins. Referring to FIGS. 14 and 15, the first set of cooling fins 640 is disposed at the main body 610 and includes a plurality of cooling fins 640a and a heat pipe 642. The heat pipe 642 connects the cooling fins 640a so that the first set of cooling fins 640 receives the thermal energy of the heat-generating components inside the electronic device through the heat pipe 642. The second set of cooling fins 650 is disposed at the rotating base 620 and includes a plurality of cooling fins 650a and a heat pipe 652. The heat pipe 652 connects the cooling fins 650a so that the second set of cooling fins 650 receives the thermal energy of the heat-generating components inside the electronic device through the heat pipe 652. The second set of cooling fins 650 is aligned with the first set of cooling fins 640, and the cooling fins 650a and the cooling fins 640a are alternately arranged and disposed. In this way, when the rotating base is closed to the retracted position from the operating position, the second set of cooling fins 160 would move to the position of FIG. 14 from the position of FIG. 15, so that the cooling fins 640a and the cooling fins 650a are alternately arranged. In this way, the first set of cooling fins 640 on the main body 610 and the second set of cooling fins 650 on the rotating base 620 are not interfered by each other so as to make the whole structure smoothly act.

In summary, the invention provides an electronic device, in which the first vent is disposed on the rotating base and the rotating base can rotate between the operating position and the retracted position relatively to the main body. When the rotating base is located at the operating position, the first vent is exposed by the electronic device so that the fan is able to blow an air-flow and the air-flow flows through the first vent to exit from the electronic device. In this way, the first vent can be exposed out of the main body to assist cooling the electronic device.

In addition, by disposing the first set of cooling fins and the second set of cooling fins respectively on the main body and the rotating base, the cooling effect is advanced, in which the first set of cooling fins and the second set of cooling fins can be disposed in dislocated way, or the cooling fins of the first set of cooling fins and the cooling fins of the second set of cooling fins can be alternately arranged and disposed, so that the first set of cooling fins and the second set of cooling fins are not interfered by each other during the rotating of the rotating base relatively to the main body so as to make the whole structure smoothly act.

It will be apparent to those skilled in the art that the descriptions above are several preferred embodiments of the present invention only, which does not limit the implementing range of the present invention. Various modifications and variations can be made to the structure of the present invention without departing from the scope or spirit of the invention.

What is claimed is:

1. An electronic device, comprising:
a main body; and
a rotating base, having a first vent, wherein the rotating base is pivoted at the main body and adapted to rotate between an operating position and a retracted position, wherein when the rotating base is located at the operating position, the first vent is exposed out of the main body, and when the rotating base is located at the retracted position, the first vent is retracted into the main body.

2. The electronic device claimed in claim 1, further comprising:
a fan module, comprising a wind-guiding cover assembly, wherein the wind-guiding cover assembly is connected between the main body and the rotating base and has a telescopic segment.

3. The electronic device claimed in claim 2, wherein the fan module further comprises a fan and the fan is fixed at the main body or the rotating base.

4. The electronic device claimed in claim 1, further comprising a motherboard disposed at the main body or the rotating base.

5. The electronic device claimed in claim 1, wherein the main body has a second vent, and when the rotating base is located at the retracted position, the first vent is located at a side of the second vent.

6. The electronic device claimed in claim 2, wherein the telescopic segment comprises a flexible portion, when the rotating base is located at the retracted position, the flexible portion is bent to shorten the telescopic segment, and when the rotating base is located at the operating position, the flexible portion is unfolded to lengthen the telescopic segment.

7. The electronic device claimed in claim 2, wherein the telescopic segment comprises a plurality of folding elements, when the rotating base is located at the retracted position, each of the folding elements is bent to shorten the telescopic segment, and when the rotating base is located at the operating position, each of the folding elements is unfolded to lengthen the telescopic segment.

8. The electronic device claimed in claim 2, wherein the telescopic segment comprises a plurality of shells, when the rotating base is located at the retracted position, the shells are sleeved by each other to shorten the telescopic segment, and when the rotating base is located at the operating position, the shells sequentially lean against each other to lengthen the telescopic segment.

9. The electronic device claimed in claim 1, further comprising:
a first set of cooling fins, disposed at the main body; and
a second set of cooling fins, disposed at the rotating base and dislocated from the first set of cooling fins, wherein when the rotating base is located at the retracted position, the second set of cooling fins is located at a side of the first set of cooling fins.

10. The electronic device claimed in claim 1, further comprising:
a first set of cooling fins, disposed at the main body and having a plurality of first cooling fins; and
a second set of cooling fins, disposed at the rotating base, aligned with the first set of cooling fins and having a plurality of second cooling fins, wherein when the rotating base is located at the retracted position, the first cooling fins and the second cooling fins are alternately arranged.
